(19) United States
(12) Patent Application Publication
(10) Pub. No.: US 2026/0359539 A1
(43) Pub. Date: Nov. 12, 2026

(54) FPGA CHIP DATA SORTING METHOD

(71) Applicant: Shenzhen Zhengyan Microelectronics Co., Ltd., Shenzhen (CN)

(72) Inventor: Xuehui Li, Yueyang (CN)

(21) Appl. No.: 19/722,301

(22) Filed: Jun. 26, 2026

(30) Foreign Application Priority Data
Nov. 7, 2025 (CN) 202511627456.5

(51) Int. Cl. G06F 30/343

(52) U.S. Cl. CPC G06F 30/343

(57) ABSTRACT

The application relates to the field of FPGA chips and data processing, and discloses an FPGA chip data sorting method, comprising performing pre-analysis on a set of digital data to determine data distribution characteristics; generating a nonlinear ramp voltage according to the data distribution characteristics; converting each digital data in the set in parallel into multiple static reference voltages; comparing the nonlinear ramp voltage with the static reference voltages in parallel and generating an event pulse upon voltage crossing; counting all generated event pulses via a global counter, and using each event pulse to independently trigger latching of a current count value of the global counter as a sorting rank of corresponding digital data; and resorting the set of digital data according to the sorting ranks. The invention adaptively optimizes the sorting process based on data distribution, effectively reducing hardware resource consumption while achieving ultra-low sorting latency.

### CROSS-REFERENCE TO RELATED APPLICATIONS

This application claims priority to Chinese Patent Application No. 202511627456.5, filed on Nov. 7, 2025, which is hereby incorporated by reference in its entirety.

### TECHNICAL FIELD

The present invention relates to the technical field of FPGA chips and data processing, and specifically to an FPGA chip data sorting method.

### BACKGROUND

FPGA (Field Programmable Gate Array) chips, due to their reconfigurability, parallel processing capability, and low latency, are widely used in fields such as modern digital signal processing, high-speed data acquisition, real-time communication, and high-performance computing. As a fundamental and core data processing operation, data sorting plays a crucial role in many FPGA applications, for example, target separation in radar signal processing, market event sorting in financial data analysis, and traffic priority scheduling in network packet processing.

At present, technical solutions for implementing data sorting on FPGA chips mainly fall into several categories. One category of parallel sorting methods are based on comparator networks. For these methods, a fixed hardware topology is constructed and a large number of parallel comparators are deployed to compare and exchange data simultaneously, thereby theoretically achieving ultra-low sorting latency, with processing time usually related to the depth of the comparator network. However, these methods require significantly increased hardware resources as the scale of the data to be sorted grows; for example, a comparator network with N elements may require a number of comparison units on the order of O (N log² N), and as a result, the logic resources on the FPGA chip will be largely occupied for processing large-scale data sets, thereby severely limiting their flexibility and scalability in practical applications.

Another category of data sorting methods are implemented through sorting algorithms with a pipelined architecture, for example, pipelined implementations based on odd-even merge sorting algorithms. In these methods, a sorting process is decomposed into multiple serial processing stages for processing only part of the data or performing part of the comparison operations, so the hardware resource consumption is controlled to a certain extent and a relatively high throughput rate is achieved thereafter. However, due to an inherent pipeline depth, a single data element has to undergo multiple clock cycles from input to the completion of final sorting, which leads to a relatively high sorting latency and makes those methods difficult to meet the stringent end-to-end latency requirements in some real-time application scenarios. In addition, there are also some methods based on the principles of counting sort or radix sort, but these methods usually impose specific constraints on the data range or number of bits, and when they are implemented in a FPGA hardware, their degree of parallelism is often limited by hardware resources and complexity, making them difficult to satisfy the ultra-low latency requirements in large-scale data processing.

In summary, currently available data sorting methods based on FPGA chips involve an inherent technical contradiction between an ultra-low sorting latency and an effectively controlled hardware resource consumption (that is, the two design objectives of a data sorting system). Increasing the parallelism alone often leads to a higher resource consumption, while introducing pipelining to save resources will increase latency. Therefore, how to design a solution that can effectively balance latency and resource consumption on an FPGA platform and realize fast, efficient, and resource-controllable sorting of large-scale data sets is an important technical challenge currently faced in this field.

### SUMMARY

In view of the deficiencies of the prior art, the present invention provides an FPGA chip data sorting method that solves the shortage of existing methods in balancing the two key performance metrics of low sorting latency and low hardware resource consumption.

To achieve the above purpose, the present invention is implemented through the following technical solution: an FPGA chip data sorting method, comprising the following steps:
acquiring a set of digital data to be sorted, which contains a plurality of digital data;
performing a pre-analysis on the set of digital data to determine data distribution characteristics, which may specifically comprise: calculating, in parallel, a maximum value and a minimum value in the set of digital data; then dividing a numerical interval determined by the maximum value and the minimum value into a preset number of sub-intervals; and finally counting the quantity of digital data falling within each sub-interval to construct a histogram that characterizes the data distribution density.
generating a nonlinear ramp voltage according to the data distribution characteristics determined in the previous step, which may specifically comprise: assigning a specific scanning time Δtₖ to a k^{th} sub-interval among the sub-intervals, wherein the scanning time is determined by the following formula:

Δtₖ=T_{base}+α·Hₖ;
Where, Δtₖ is a scanning time allocated to the k^{th} sub-interval; Hₖ is a quantity of digital data falling within the k^{th} sub-interval in the histogram; T_{base} is a preset base time constant; α is a preset density influence weighting coefficient. Based on the scanning time allocated to each sub-interval, a piecewise linear ramp voltage that is not linear overall but linear within each time segment can be generated, whose change slope within a voltage range of each sub-interval is inversely proportional to the scanning time Δtₖ allocated to that sub-interval.
converting each digital data in the set in parallel into multiple static reference voltages, wherein the static reference voltage V_{refi} for any digital data Dᵢ in the set is determined by the following formula:

$${V}_{refi} = {Vmin}_{eff} + \frac{{D}_{i} - {D}_{min}}{{D}_{max} - {D}_{min}} \cdot ( {V}_{{max}_{eff}} - {V}_{{min}_{eff}} ) ;$$

Where, Vrefᵢ is the static reference voltage of the digital data Dᵢ; Dᵢ is any digital data in the set of digital data; Dₘₐₓ is a maximum value of the set of digital data; Dₘᵢₙ is a minimum value of the set of digital data. Vmax_{eff} is an upper limit of a preset effective analog voltage range; Vmin_{eff} is a lower limit of the preset effective analog voltage range.
comparing the nonlinear ramp voltage with the plurality of static reference voltages in parallel, and generating, when a voltage value of the nonlinear ramp voltage crosses a voltage value of any one of the static reference voltages, an event pulse corresponding to that static reference voltage.
counting all generated event pulses via a global counter, and using each event pulse to independently trigger latching of a current count value of the global counter as a sorting rank of corresponding digital data, which is specifically characterized that, all generated event pulses can be merged through an OR-gate tree structure into a global pulse sequence, and the global pulse sequence is input to an asynchronous counter for cumulative counting; and each individual event pulse, while being merged, is also used as a latch enable signal to trigger latching of a current count value of the global counter before the count value increases due to that pulse.
resorting the set of digital data according to the obtained sorting ranks to output sorted data, which can be implemented by a crossbar switch network that routes each digital data in the set in parallel to the correct output position using the sorting rank of the digital data as a target address.

In another aspect, the invention provides an FPGA chip data sorting system, which comprises:
a pre-analysis module configured to perform pre-analysis on a set of digital data to be sorted to determine data distribution characteristics;
a ramp generation module, an input of which is connected to an output of the pre-analysis module and which is configured to generate a nonlinear ramp voltage according to the data distribution characteristics;
a parallel conversion module configured to convert each digital data in the set in parallel into multiple static reference voltages;
a parallel comparison module, inputs of which are respectively connected to outputs of the ramp generation module and the parallel conversion module, and which is configured to compare the nonlinear ramp voltage with the static reference voltages in parallel and to generate an event pulse when a voltage value of the nonlinear ramp voltage crosses a voltage value of any one of the static reference voltages;
a sorting rank determination module, an input of which is connected to an output of the parallel comparison module and which is configured to count all generated event pulses via a global counter and to use each event pulse to independently trigger latching of a current count value of the global counter as a sorting rank of corresponding digital data; and
a data resorting module, an input of which is connected to an output of the sorting rank determination module and which is configured to resort the set of digital data according to the sorting ranks to output sorted data.

The invention provides an FPGA chip data sorting method, which has the following beneficial effects:

1. The invention performs a pre-analysis on a set of digital data to determine data distribution characteristics and generates a nonlinear ramp voltage according to the data distribution characteristics, thereby realizing adaptive optimization of the sorting process. Specifically, in numerical intervals where data are dense, it allocates a longer scanning time to reduce the change rate of the voltage ramp, thereby effectively improving the comparison resolution and sorting accuracy in those intervals; whereas in intervals where data are sparse, it performs fast scanning to shorten the overall sorting time, thereby achieving a balance between sorting performance and efficiency.

2. The invention converts the digital data to be sorted in parallel into multiple static reference voltages and applies a parallel voltage comparison array to compare the static reference voltages synchronously with a single global ramp voltage, thereby converting a numerical sorting into a time-event sorting and achieving ultra-low sorting latency. The core time required for the entire sorting operation is as short as the scanning time of one analog ramp voltage, and this time is independent of complicated digital logic iterations or large-scale data migration, which makes the method according to this invention particularly suitable for real-time data processing application scenarios that have stringent requirements on processing latency.

3. The invention integrates a global counter to uniformly count all event pulses generated in parallel and uses each event pulse to independently trigger latching of a current count value of the global counter to determine a sorting rank. With time-domain information applied ingeniously to replace a complicated spatial comparison network, the invention significantly optimizes hardware resource utilization efficiency while ensuring a high degree of parallelism. Compared with a fully parallel numerical sorting network that requires a large number of comparison units, the invention allows for sorting with only N comparators and latches and one shared global counter, thereby effectively controlling resource consumption when implementing large-scale parallel data sorting on an FPGA chip.

### BRIEF DESCRIPTION OF THE DRAWINGS

FIG. 1 is a flowchart of the method according to the invention;

FIG. 2 is a system architecture diagram of the invention.

### DETAILED DESCRIPTION OF EMBODIMENTS

A clear and complete description of the technical solutions in the present invention will be given below, in combination with the drawings corresponding to the embodiments of the present invention. Apparently, the embodiments described below are some, but not all, of the embodiments of the present invention. All of the other embodiments, obtained by those of ordinary skill in the art on the basis of the embodiments of the present invention without any inventive efforts, fall within the protection scope of the present invention.

### Embodiment

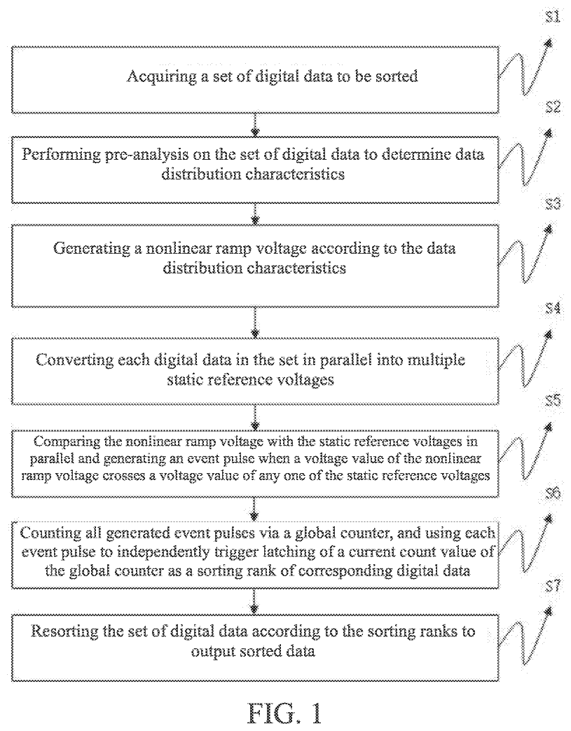

As shown in FIG. 1, an embodiment of the invention provides an FPGA chip data sorting method, which comprises the following steps:

### S1: Acquiring a Set of Digital Data to be Sorted;

The step of acquiring a set of digital data to be sorted in this embodiment is the initial stage of the sorting method according to the invention, which not only includes receiving the data, but also covers a series of parallel preprocessing operations performed on the set of data, with an aim to provide necessary physical parameters and analog references for a subsequent core step of nonlinear time-domain mapping-based sorting.

Specifically, the method first loads a data set containing N digital data into a dedicated input register array through a data interface or an internal bus of an FPGA chip, so as to complete the acquisition and temporary storage of the entire set of digital data inside the FPGA chip, where the set of digital data is denoted as D={D₀, D₁, . . . , D_{N-1}}.

After the set of digital data is completely acquired, the invention, instead of performing sorting and comparison immediately, first activates a digital pre-analysis unit to carry out parallel hardware-level statistical analysis on all N digital data in the register array, so as to grasp the overall distribution profile of the data set and thereby adaptively adjust key parameters of the subsequent analog sorting process.

The pre-analysis step further comprises parallel calculation of a maximum value Dₘₐₓ and a minimum value Dₘᵢₙ of the set of digital data. Preferably, the calculation of the maximum value Dₘₐₓ and the minimum value Dₘᵢₙ is implemented by means of a parallel comparator tree network, which can complete global extremum searching over the N digital data within very few clock cycles to ensure high pre-analysis efficiency.

After the numerical range [Dₘᵢₙ, Dₘₐₓ] of the data is determined, the digital pre-analysis unit then measures the distribution density of the data. To this end, the system divides this numerical range into M sub-intervals of equal width, wherein the width of each sub-interval, W_{bin}, is determined by the following formula:

$${W}_{bin} = \frac{{{D}_{max} - {D}_{min}}^{\text{?}}}{M} ;$$

For any digital data Dᵢ in the set, the system calculates in parallel the index kᵢ of the sub-interval into which the data falls:

$${K}_{i} = \frac{{D}_{i} - {D}_{min}}{{W}_{bin}} ;$$

The system configures an independent accumulating counter for each sub-interval, which performs parallel judgment and accumulation operations to finally count the number of digital data falling into the sub-interval, thereby forming a histogram vector H={H₀, H₁, . . . , H_{M-1}} capable of characterizing the data distribution density for use as the core basis for the generation of a nonlinear ramp voltage in subsequent steps.

While the pre-analysis on the set of digital data is being completed, or in a step immediately following the completion of data pre-analysis, the acquired set of digital data is sent from the input register array into a parallel conversion module, namely a parallel digital-to-analog conversion (DAC) array, mapping discrete digital quantities to continuous analog voltage values to provide a physical reference for subsequent voltage comparison operations.

Specifically, the static reference voltage V_{refi} for any digital data Dᵢ in the set of digital data is converted and determined by the following formula:

$${V}_{refi} = {Vmin}_{eff} + \frac{{D}_{i} - {D}_{min}}{{D}_{max} - {D}_{min}} \cdot ( {V}_{{max}_{eff}} - {V}_{{min}_{eff}} ) ;$$

Where, V_{refi} is the static reference voltage generated after conversion of the digital data Dᵢ; Dᵢ is the digital data currently to be converted; Dₘₐₓ and Dₘᵢₙ are respectively the maximum value and the minimum value calculated in the aforementioned pre-analysis step; Vmax_{eff} and Vmin_{eff} are respectively the upper limit and the lower limit of the preset effective analog voltage range of the system. This parallel conversion process is executed simultaneously by N independent DAC units, so that N static reference voltages can be generated quickly and established stably. This mapping relationship ensures that the magnitude relationship in the digital domain can be converted linearly and order-preservingly into the high-low relationship in the analog voltage domain, which is the basis for correct sorting.

At this point, the preliminary processing for the acquisition of a set of digital data to be sorted has been completed, and it generates two outputs: on the one hand, the pre-analysis yields the histogram vector H describing the data distribution characteristics, which is sent to a ramp generation module to control the waveform of the nonlinear ramp voltage; on the other hand, the parallel conversion yields N static reference voltages Vrefᵢ representing the magnitudes of the respective data, which are sent to a parallel comparison module as comparison references. Through the above steps, the invention successfully transforms the acquired unsorted digital data set into a set of analog parameters that are precisely calibrated to perform time-domain mapping-based sorting.

### S2: Performing Pre-Analysis on the Set of Digital Data to Determine Data Distribution Characteristics;

The step of performing pre-analysis on the set of digital data to determine data distribution characteristics in this embodiment is a key preliminary processing stage in the sorting method according to the invention. This step is designed to perform high-speed parallel statistics on the complete set of data to be sorted in the digital domain and to extract key quantitative metrics that can characterize the overall profile and local density of the data set, thereby providing precise control parameters for the subsequent adaptive nonlinear time-domain mapping process.

Specifically, after the set of digital data D={D₀, D₁, . . . , D_{N-1}} is acquired and temporarily stored in an internal register array of the FPGA chip, a digital pre-analysis unit is activated to perform the pre-analysis task.

The pre-analysis process first comprises parallel calculation of a maximum value Dₘₐₓ and a minimum value Dₘᵢₙ of the set of digital data, so as to accurately define the numerical range of the data set. Preferably, the calculation of maximum value and the minimum value is directly implemented in a hardware logic by means of a parallel tree-structured comparator network, which can complete global extremum searching over all N data within very few clock cycles, thereby ensuring the pre-analysis efficiency. The maximum value Dₘₐₓ and minimum value Dₘᵢₙ calculated therefrom not only define the boundary of data analysis, but also provide the necessary normalization reference for subsequently mapping of digital quantities to analog reference voltages.

After the numerical range [Dₘᵢₙ, Dₘₐₓ] of the data is determined, this pre-analysis step further measures the distribution density of the data within this range. To this end, the system divides this numerical range into M sub-intervals, wherein the width of each sub-interval, W_{bin}, is determined by the following formula:

$${W}_{bin} = \frac{{D}_{max} - {D}_{min}}{M} ;$$

Where, M is a preset integer, which determines the granularity of the distribution density analysis.

For any digital data Dᵢ in the set, the system calculates in parallel the index kᵢ of the sub-interval into which the data falls via a dedicated hardware computation unit following a computation logic defined in the following formula:

$${K}_{i} = \frac{{D}_{i} - {D}_{min}}{{W}_{bin}} ;$$

Where, “•” denotes the floor operation. This computation is carried out simultaneously for all N data.

To complete the density statistics, the system is configured with an independent accumulation counter for each of the M sub-intervals. By determining in parallel the sub-interval index kᵢ corresponding to each data Dᵢ and performing an increment-by-one operation on the corresponding kᵢ^{th} counter, the system can efficiently count the exact number of digital data falling into each sub-interval. After this process is completed, a histogram vector H={H₀, H₁, . . . , H_{M-1}} that fully characterizes the data distribution density is generated, where the k^{th} component of the vector, Hₖ, is the total number of digital data falling into the k^{th} sub-interval.

The pre-analysis step finally outputs a set of data with statistical characteristic, including the maximum value Dₘₐₓ, the minimum value Dₘᵢₙ, and the histogram vector H. This set of data is then transmitted to a ramp generation module as the core basis for generating an adaptive nonlinear ramp voltage, so that the subsequent analog sorting process can be dynamically optimized according to the actual distribution of the data to be sorted, thereby offering a higher resolution in numerical intervals where the data are dense.

### S3: Generating a Nonlinear Ramp Voltage According to the Data Distribution Characteristics;

The step of generating a nonlinear ramp voltage according to the data distribution characteristics in this embodiment is the core link by which the method according to the present invention achieves adaptive sorting. This step uses the statistical results from the aforementioned pre-analysis step as inputs, which are converted into a precisely modulated, dynamically varying analog voltage signal for use as a global time reference in the subsequent parallel comparison process.

Specifically, the ramp generation module, after receiving the maximum value Dₘₐₓ, the minimum value Dₘᵢₙ, and the histogram vector H={H₀, H₁, . . . , H_{M-1}} output from the digital pre-analysis units, first plans, in the digital domain, an optimal time path for the subsequent analog voltage scanning process.

The planning is primarily intended to allocate different scanning times to the voltage segments corresponding to the respective sub-intervals of the histogram, following the principle that, in intervals where data points are dense, a longer scanning time is assigned to achieve a more gradual voltage change and thereby improve the sorting resolution in that interval, whereas in intervals where data points are sparse, a shorter scanning time is assigned to enable quick scan-through and optimize the overall sorting efficiency.

To achieve the above purpose, the system allocates a scanning time Δtₖ to the k^{th} sub-interval, wherein the scanning time is calculated by the following formula:

Δtₖ=T_{base}+α·Hₖ;
Where,
Δtₖ is the scanning time allocated to the k^{th} sub-interval;
Hₖ is the number of digital data of the k^{th} sub-interval in the histogram, which directly reflects the data density in that interval;
T_{base} is a preset base time constant, which is defined to ensure that a minimum scanning time is allocated even when there are no data points in a certain sub-interval (that is, Hₖ=0), thereby avoiding the physically impossible situation in which the voltage slope becomes infinite;
α is a preset density influence weighting coefficient, which is defined to adjust the degree to which the data density Hₖ influences the scanning time Δtₖ.

After the scanning time of each sub-interval has been determined, the total time Tᵣₐₘₚ required for the entire nonlinear ramp scan can be obtained by summing the scanning times of all sub-intervals:

$${T}_{ramp} = {\sum }_{k = 0}^{M - 1} Δ {t}_{k} ;$$

Subsequently, the system associates this time allocation plan with the voltage range to define a complete ramp voltage function. First, the boundaries of the numerical sub-intervals are linearly mapped to the effective analog voltage range [Vmax_{eff}, Vmin_{eff}] of the system, and the starting voltage Vₖ and ending voltage Vₖ₊₁ of the k^{th} voltage sub-interval can be determined.

Then, the starting time Tₛₜₐᵣₜₖ of the k^{th} time interval is defined as follows:

$${T}_{{start}_{k}} = {\sum }_{j = 0}^{k - 1} Δ {t}_{j} ;$$

Where, Tₛₜₐᵣₜ₀ is defined as 0.

Based on the above parameters, when the time t falls within the k^{th} time interval [Tₛₜₐᵣₜₖ,Tₛₜₐᵣₜₖ±Δtₖ)

the functional expression of the nonlinear ramp voltage Vᵣₐₘₚ(t) is precisely defined as follows:

$${V}_{ramp ( t )} = {V}_{k} + \frac{( Vk + 1 - Vk ) \cdot ( t - Tstartk )}{Δ {t}_{k}} ;$$

This function describes a voltage waveform that is piecewise linear with respect to time. Since the duration Δtₖ of each segment varies dynamically with the data density Hₖ, the voltage slope of each segment (whose magnitude is proportional to (Vₖ₊₁−Vₖ)/Δtₖ) is different, and therefore, over the entire scanning period Tᵣₐₘₚ, the overall behavior of the ramp voltage is nonlinear.

Preferably, the generation of the nonlinear ramp voltage can be implemented by a numerically controlled voltage generator, for example, by a high-precision digital-to-analog converter that is driven at its input by digital control codes provided in real time by the digital logic inside an FPGA chip according to the above piecewise function.

Ultimately, this step outputs a single, continuously varying analog voltage signal Vᵣₐₘₚ₍ₜ₎, which is broadcast to the N comparators of the parallel comparison module as the common dynamic comparison reference of those comparators. It is precisely due to the nonlinear characteristics of this ramp voltage that the invention can adaptively optimize the sorting process in the time domain, without the need to increase the hardware resources, that is the comparators.

S4: Converting Each Digital Data in the Set in Parallel into Multiple Static Reference Voltages;

The step of converting each digital data in the set in parallel into multiple static reference voltages in this embodiment is a key link in the method according to the invention for implementing digital-to-analog conversion and establishing a physical reference for the subsequent time-domain comparison process. Executed in parallel with, or immediately after, the aforementioned pre-analysis step, this step is intended to efficiently and order-preservingly map the N discrete digital data (quantities) to be sorted into N independent analog voltage values that remain stable throughout the entire sorting event.

Specifically, this step is performed by a parallel conversion module, that is, a parallel digital-to-analog conversion array. The array is composed of N independent DAC units with identical structure and performance parameters, and each DAC unit corresponds to one digital data in the digital data set D={D₀, D₁, . . . , D_{N-1}} to be sorted.

After the set of digital data is acquired, each digital data Dᵢ in the set is respectively routed to the digital input of the i^{th} DAC unit corresponding thereto. All N DAC units are enabled synchronously to start the conversion process at the same time.

The conversion logic of each DAC unit follows a conversion rule that linearly maps the input numerical value to a preset effective analog voltage range [Vmax_{eff}, Vmin_{eff}], using the maximum Dₘₐₓ and minimum Dₘᵢₙ of the data set calculated by the digital pre-analysis unit as normalization references. For any digital data Dᵢ, the corresponding static reference voltage V_{refi} is determined by the following formula:

$${V}_{refi} = {Vmin}_{eff} + \frac{{D}_{i} - {D}_{min}}{{D}_{max} - {D}_{min}} \cdot ( {V}_{{max}_{eff}} - {V}_{{min}_{eff}} ) ;$$

Where,
V_{refi} is the static reference voltage output by the i^{th} DAC unit and uniquely corresponding to the digital data Dᵢ;
Dᵢ is the digital data currently to be converted;
Dₘₐₓ is the maximum value of the digital data set calculated in the aforementioned pre-analysis step;
Dₘᵢₙ is the minimum value of the digital data set calculated in the aforementioned pre-analysis step;
Vmax_{eff} is a system preset upper limit of the effective analog voltage range;
Vmin_{eff} is a lower limit of the effective analog voltage range;

This mathematical mapping relationship ensures two key technical characteristics: first, the conversion is order-preserving, that is, if two digital data satisfy a magnitude relationship Dᵢ>Dⱼ in the digital domain, then the converted analog reference voltages of the two data also necessarily satisfy the same magnitude relationship in the voltage domain; V_{refi}>V_{refi}.

second, the conversion makes full use of the dynamic range of the system analog voltage. By completely mapping the actual numerical range [Dₘᵢₙ, Dₘₐₓ] of the data to the voltage range [Vmax_{eff}, Vmin_{eff}], it maximizes the absolute difference between the reference voltages corresponding to different numerical values, thereby providing favorable conditions for subsequent high-precision voltage comparison.

Preferably, each DAC unit in the parallel digital-to-analog conversion array can be implemented through an R-2R ladder network structure or a current-steering structure to ensure the conversion speed and linearity.

Ultimately, this step outputs N independent and stable simulated direct-current voltages Vref₀, Vref₁, . . . , Vref_{N-1}, which, after being generated, remain constant throughout the subsequent nonlinear ramp voltage scanning process. Each static reference voltage V_{refi} is respectively input to one input terminal of the i^{th} voltage comparator in the parallel comparison module, as a static comparison reference of the comparator.

S5: Comparing the Nonlinear Ramp Voltage with the Static Reference Voltages in Parallel and Generating an Event Pulse when a Voltage Value of the Nonlinear Ramp Voltage Crosses a Voltage Value of any One of the Static Reference Voltages;

The step of comparing the nonlinear ramp voltage with the static reference voltages in parallel and generating an event pulse when a voltage value of the nonlinear ramp voltage crosses a voltage value of any one of the static reference voltages in this embodiment is the stage in the method according to the invention at which the core physical process of sorting is executed. In this step, the dynamic analog signal representing global time that is generated in the preceding step is compared in real time and in parallel with the static analog signals representing the magnitude of each piece of data, with the purpose of accurately converting the magnitude relationship of the N data in the digital domain into the chronological order in which the N events occur in the time domain.

Specifically, this step is performed by a parallel voltage comparison and pulse generation array, which structurally consists of N independent high-speed voltage comparators and edge detection and pulse generation circuits that correspond one-to-one to each comparator.

This process uses two types of input signals: one is a single global nonlinear ramp voltage Vᵣₐₘₚ(t) output by the ramp generation module and broadcast to all of the N comparators; the other is N independent static reference voltages Vrefᵢ output by the parallel conversion module and respectively sent to the N comparators.

In operation, for the i^{th} comparison unit (i=0, 1, . . . , N−1) in the array, one input terminal of its voltage comparator receives the global Vᵣₐₘₚ(t) signal, while the other input terminal receives its dedicated static reference voltage Vrefᵢ. Throughout the entire ramp scanning period Tᵣₐₘₚ, all of the N voltage comparators operate continuously, determining in real time the relative magnitude of the voltages at their two input terminals, and outputting a corresponding binary logic level.

As time t elapses, the value of the nonlinear ramp voltage Vᵣₐₘₚ(t) increases monotonically. For each static reference voltage Vrefᵢ, there must be a unique moment tᵢ at which the value of the ramp voltage is exactly equal to the value of the reference voltage, wherein the moment tᵢ is defined by the following fomula:

Vramp(tᵢ)=V^{refi};

Before the moment ti, Vᵣₐₘₚ(t)<Vrefᵢ, holds, and the comparator outputs one logic state (for example, logic “0”); after the moment ti, Vᵣₐₘₚ(t)<Vrefᵢ holds, and the comparator flips to the other logic state. The exact instant at which this logic state flip occurs is the voltage crossing event as defined by the present invention. Since the preceding step has proven a one-to-one correspondence between the magnitude relationship of the original data Dᵢ and the high-low relationship of the reference voltages Vrefi, the chronological order ti in which the voltage crossing events occur faithfully reflects the sorting of the original data.

To capture this instantaneous event accurately, the output of each voltage comparator is connected to a dedicated edge detection and pulse generation circuit which is configured to be sensitive only to a specific logic level transition at the comparator output. If and only if the preset edge transition is detected, the circuit immediately generates a standard digital logic pulse with an extremely narrow pulse width. This pulse is the event pulse, denoted as Pᵢ.

To ensure accurate time capture of the voltage crossing event, an analog voltage comparator with low response latency and high conversion rate is preferred. The pulse generation circuit can be implemented by simple digital logic gates.

Ultimately, this step outputs N independent event pulse signals P₀, P₁, . . . , P_{N-1}. For each of these N signals, the moment tᵢ when each pulse Pᵢ occurs is different, and the chronological order of these moments directly corresponds to the sorting of the original data Dᵢ in an increment order. These event pulses are then sent in parallel to a sorting rank determination module as precise time beacons for triggering counting and latching operations.

### S6: Counting all Generated Event Pulses Via a Global Counter, and Using Each Event Pulse to Independently Trigger Latching of a Current Count Value of the Global Counter as a Sorting Rank of Corresponding Digital Data;

The step of counting all generated event pulses via a global counter, and using each event pulse to independently trigger latching of a current count value of the global counter as a sorting rank of corresponding digital data in this embodiment is the stage that implements the core function of converting time-domain sorting into numerical ranks in the method according to the invention. This step aims to efficiently convert the N independent events, which have already been sorted in time by the preceding step, into a set of numerical sorting positions from 0 to N−1.

Specifically, this step is performed by a sorting rank determination module. This step uses the N independent event pulse signals P₀, P₁, . . . , P_{N-1} output from the aforementioned parallel comparison and pulse generation array as the inputs. Before the sorting process starts, a global counter in the module is initialized and reset.

To achieve unified counting of all event pulses, the system first merges all the N independent event pulses Pᵢ into a single global pulse sequence P_{global} via a global pulse merging unit. Preferably, the global pulse merging unit may be implemented by a large-scale OR-gate tree structure, which can pass any input pulse signal to its output with ultra-low latency.

The global pulse sequence P_{global} is then used as a counting clock input of a global counter. In this description, the global counter is denoted as Cᵣₐₙₖ, and its bit width is sufficient to represent the value N−1. Whenever a pulse occurs in the global pulse sequence P_{global}, the count value of Cᵣₐₙₖ is incremented by one. A high-speed asynchronous counter is preferred for the global counter, so as to ensure a quick response to all pulses that arrive in rapid succession without missing. Therefore, the count value Cᵣₐₙₖ(t) at any moment t represents the total number of voltage crossing events that have occurred from the beginning of sorting up to that moment.

In parallel with the global counting, the system further provides a parallel rank latching array that contains N independent latches L₀, L₁, . . . , L_{N-1}, with each latch in one-to-one correspondence with one original data Dᵢ.

A key technical feature of the invention lies in that, while each event pulse Pᵢ is sent to the global pulse merging unit, its signal is also directly and independently routed to the latch enable terminal of the i^{th} latch Lᵢ. At the same time, the data input terminals of all the N latches are connected in parallel to an output bus of the global counter Cᵣₐₙₖ.

At the exact moment tᵢ when a voltage crossing event occurs, the event pulse Pᵢ is generated and triggers two parallel actions: enabling the value of the global counter Cᵣₐₙₖ to increment as a part of the merged signal; and instructing the corresponding latch Lᵢ to act immediately as an independent latch-enable signal.

At the moment tᵢ, the latch Lᵢ is triggered by the pulse Pᵢ and captures and stores the instantaneous value of the global counter Cᵣₐₙₖ at that moment. The latched count value is defined as the sorting rank Rᵢ of the original digital data Dᵢ, that is,

Rᵢ=Cᵣₐₙₖ(tᵢ);

Since the path delay for the signal to travel from the generation point Pᵢ to the dedicated latch Lᵢ is significantly shorter than the total path delay required for the signal to pass through the global pulse merging unit and finally trigger an update of the state of the counter Cᵣₐₙₖ, the latch Lᵢ captures the count value of the counter before the increment operation induced by the pulse Pᵢ is completed. This inherent timing relationship causes the event pulses to latch successive count values—0 for the first pulse, 1 for the second, and so on, with the N^{th} pulse latching count value N−1.

When the entire ramp scanning period Tᵣₐₘₚ ends, all voltage crossing events have occurred, and in the N latches of the parallel rank latching array, there are stably stored, respectively and in a one-to-one correspondence with the original data D₀, . . . , D_{N-1}, unique sorting ranks R₀, . . . , R_{N-1} ranging from 0 to N−1.

This set of N pieces of pairing information constitutes the final output of this step and is sent to a data resorting module as the direct basis for performing physical resorting

### S7: Resorting the Set of Digital Data According to the Sorting Ranks to Output Sorted Data.

The step of resorting the set of digital data according to the sorting ranks to output sorted data in this embodiment is the final execution stage of the complete sorting process according to the invention. The purpose of this step is to materialize the numerical ranks, which are determined in the previous steps to represent the logical order, into a spatial resorting of the data to be sorted on a physical storage or transmission medium, thereby generating a final data sequence that is monotonically sorted in an increment or decrement order in value.

Specifically, this step is carried out by a data resorting module. The input of this module includes two sets of parallel information that are aligned in time: one is a set of digital data D={D₀, D₁, . . . , D_{N-1}} to be sorted with the original input order preserved, which is usually temporarily stored in an input buffer register array; the other is a set of sorting ranks R={R₀, R₁, . . . , R_{N-1}} output by the parallel rank latching array of the aforementioned sorting rank determination module, which are in one-to-one correspondence with the original data. At this time, the system has obtained in parallel N data-rank pairs {(D₀, R₀), (D₁, R₁), . . . , (Dₙ₋₁, Rₙ₋₁)/}.

The intrinsic logical relationship of the resorting operation aims to create a new sorted output data set D_{sorted}. This relationship can be precisely described by the following formula:

∀i∈{0,1,∀i∈{0,1, . . . ,N−1},D_{sorted}[i]=Di;

This formula indicates that, for any original data Dᵢ, its sorting rank Rᵢ directly defines the position index that it should occupy in the final sorted data set D_{sorted}.

To implement this parallel data routing operation efficiently in hardware, a crossbar switch network structure with N inputs and N outputs is preferred for the the data resorting module, with a function to establish an arbitrary connection path between input ports and output ports according to external control signals.

In this application scenario, the N input ports of the crossbar switch network are respectively connected to output terminals of registers that temporarily store the original data D₀, . . . , D_{N-1}; the N output ports constitute the final output bus for the sorted data; and the routing behavior of the network is completely controlled by the set of sorting ranks R₀, . . . , R_{N-1}.

Specifically, for the i^{th} input port of the crossbar switch network, the routing control signal is its paired sorting rank Rᵢ. The control signal Rᵢ instructs the internal logic of the crossbar switch network to establish a data path from the i^{th} input port to the Rᵢ^{th} output port. Since R₀, . . . , R_{N-1} in the set of sorting ranks constitute a complete set that contains all integers from 0 to N−1 without repetition, this parallel routing operation is able to identify a unique output port for each input data, thereby avoiding any data conflict.

When all N sorting ranks are applied to the control terminals of the crossbar switch network simultaneously, N data paths inside the network are established instantaneously. All data in the original data set D are then transmitted through these configured paths in parallel to their respective correct positions on the output bus in a single operation.

Ultimately, this step outputs a completely sorted data sequence D_{sorted} that is stably present at the N output ports of the data resorting module. This data sequence can be directly used by subsequent processing units or written into an output memory. At this point, the complete process of the FPGA chip data sorting method according to the invention has been completed.

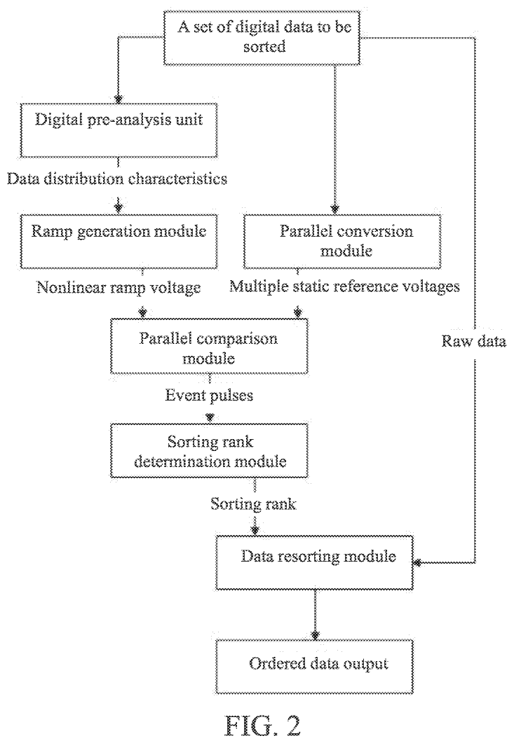

As shown in FIG. 2, an FPGA chip data sorting system comprises:
a pre-analysis module configured to perform pre-analysis on a set of digital data to be sorted to determine data distribution characteristics;
a ramp generation module configured to generate a nonlinear ramp voltage according to the data distribution characteristics; a parallel conversion module configured to convert each digital data in the set in parallel into multiple static reference voltages;
a parallel comparison module configured to compare the nonlinear ramp voltage with the static reference voltages in parallel and to generate an event pulse when a voltage value of the nonlinear ramp voltage crosses a voltage value of any one of the static reference voltages;
a sorting rank determination module configured to count all generated event pulses via a global counter and to use each event pulse to independently trigger latching of a current count value of the global counter as a sorting rank of corresponding digital data;
a data resorting module configured to resort the set of digital data according to the sorting ranks to output sorted data.

Although embodiments of the present invention have been illustrated and described, it can be understood that various changes, modifications, substitutions, and alterations may be made therein by those of ordinary skill in the art without departing from the principles and spirit of the present invention, and should also fall within the scope of the present invention defined by the appended claims and equivalents thereof.

What is claimed is:

1. An FPGA chip data sorting method, characterized in that it comprises the following steps:
S1: acquiring a set of digital data to be sorted;
S2: performing pre-analysis on the set of digital data to determine data distribution characteristics;
S3: generating a nonlinear ramp voltage according to the data distribution characteristics;
S4: converting each digital data in the set in parallel into multiple static reference voltages;
S5: comparing the nonlinear ramp voltage with the static reference voltages in parallel and generating an event pulse when a voltage value of the nonlinear ramp voltage crosses a voltage value of any one of the static reference voltages;
S6: counting all generated event pulses via a global counter, and using each event pulse to independently trigger latching of a current count value of the global counter as a sorting rank of corresponding digital data;
S7: resorting the set of digital data according to the sorting ranks to output sorted data.

2. The method according to claim 1, characterized in that the step of performing pre-analysis on the set of digital data to determine data distribution characteristics comprises:
calculating, in parallel, a maximum value and a minimum value of the set of digital data; and
dividing a numerical interval determined by the maximum value and the minimum value into several sub-intervals, and counting a quantity of digital data falling within each sub-interval to construct a histogram that describes data distribution density.

3. The method according to claim 2, characterized in that the step of generating a nonlinear ramp voltage according to the data distribution characteristics comprises:
allocating a scanning time Δtₖ to a k^{th} sub-interval, wherein the scanning time is determined by the following formula:
Δtₖ=T_{base}+α·Hₖ;
Where,
Δtₖ is a scanning time allocated to the k^{th} sub-interval;
Hₖ is a quantity of digital data falling within the k^{th} sub-interval in the histogram;
T_{base} is a preset base time constant;
α is a preset density influence weighting coefficient; generating a nonlinear ramp voltage based on the scanning time allocated to each sub-interval.

4. The method according to claim 3, characterized in that the nonlinear ramp voltage is a piecewise linear voltage, and a voltage change slope thereof within a voltage range of each sub-interval is inversely proportional to the scanning time Δtₖ allocated to the sub-interval.

5. The method according to claim 1, characterized in that the step of counting all generated event pulses via a global counter comprises:
merging all generated event pulses into a global pulse sequence through an OR-gate tree structure; and inputting the global pulse sequence to an asynchronous counter as a global counter.

6. The method according to claim 2, characterized in that the step of converting each digital data in the set in parallel into multiple static reference voltages comprises:
the static reference voltage Vrefᵢ for any digital data Dᵢ in the set of digital data is determined by the following formula:
$${V}_{refi} = {Vmin}_{eff} + \frac{{D}_{i} - {D}_{min}}{{D}_{max} - {D}_{min}} \cdot ( {V}_{{max}_{eff}} - {V}_{{min}_{eff}} ) ;$$
Where,
Vrefᵢ is the static reference voltage of the digital data Dᵢ;
Dᵢ is any digital data in the set of digital data;
Dₘₐₓ is a maximum value of the set of digital data;
Dₘᵢₙ is a minimum value of the set of digital data.
Vmax_{eff} is an upper limit of a preset effective analog voltage range;
Vmin_{eff} is a lower limit of the preset effective analog voltage range.

7. The method according to claim 1, characterized in that the step of resorting the set of digital data according to the sorting ranks comprises:
routing each digital data in the set in parallel to an output position through a crossbar switch network by using the sorting rank as a target address.

8. The method according to claim 2, characterized in that a time point when an event pulse occurs is jointly determined by a voltage value of the nonlinear ramp voltage and a voltage value of the static reference voltages; the generation of the nonlinear ramp voltage depends on the histogram; and the construction of the histogram depends on the set of digital data.

9. The method according to claim 1, characterized in that each event pulse is simultaneously used to trigger an increase of a count value of the global counter; and as a latch enable signal to trigger latching of a current count value of the global counter before the count value increases.

10. An FPGA chip data sorting system, based on the FPGA chip data sorting method according to claim 1, characterized in that it comprises:
a pre-analysis module configured to perform pre-analysis on a set of digital data to be sorted to determine data distribution characteristics;
a ramp generation module configured to generate a nonlinear ramp voltage according to the data distribution characteristics; a parallel conversion module configured to convert each digital data in the set in parallel into multiple static reference voltages;
a parallel comparison module configured to compare the nonlinear ramp voltage with the static reference voltages in parallel and to generate an event pulse when a voltage value of the nonlinear ramp voltage crosses a voltage value of any one of the static reference voltages; a sorting rank determination module configured to count all generated event pulses via a global counter and to use each event pulse to independently trigger latching of a current count value of the global counter as a sorting rank of corresponding digital data; and
a data resorting module configured to resort the set of digital data according to the sorting ranks to output sorted data.
